(19) United States
(12) Patent Application Publication
(10) Pub. No.: US 2006/0157835 A1
(43) Pub. Date: Jul. 20, 2006

(54) Semiconductor device and method of fabricating same

(76) Inventors: Fumihiko Ooka, Miyazaki-gun (JP); Makoto Saito, Miyazaki-gun (JP)

Correspondence Address: RABIN & Berdo, PC, 1101 14TH STREET, NW, SUITE 500, WASHINGTON, DC, 20005, US

(21) Appl. No.: 11/330,095

(22) Filed: Jan. 12, 2006

(30) Foreign Application Priority Data
Jan. 19, 2005 (JP) 2005-011995

(51) Int. Cl. H01L 23/02

(52) U.S. Cl. 257/678

(57) ABSTRACT

A semiconductor device has a bottomless package and a semiconductor chip. The semiconductor chip is disposed in a chip installation-side opening in a chip storage space of the package. The semiconductor device also has a sealing lid that lies opposite the upper face of the semiconductor chip and covers the lid-side opening of the package. The semiconductor device also has a binding layer that seals the gap between the side face of the semiconductor chip and the side face of the chip installation-side opening and secures the semiconductor chip.

### BACKGROUND OF THE INVENTION

1. Field of the Invention

The present invention relates to a semiconductor device that includes a package for hermetically sealing a semiconductor chip and to a method of fabricating the same.

2. Description of the Related Art

In the case of conventional semiconductor devices, a package having a bottom is constituted by a rectangular ceramic substrate, a frame-like seam ring that is formed around the ceramic substrate, and a ring-like ceramic substrate that is formed on the inner periphery of the seam ring. The semiconductor chip is mounted at the center of the ceramic substrate constituting the bottom face of the chip storage space formed inside the package. A metal lid covers (closes) an opening of the chip storage space on the opposite side of the semiconductor chip. Thus, the semiconductor chip placed in the chip storage space is hermetically sealed. This is disclosed in Japanese Patent Application Kokai (Laid Open) No. 2002-198452 (page 3, paragraph 0021 to page 4, paragraph 0032, FIG. 1).

In the above-described conventional technology, the ceramic substrate is used as the bottom plate of the package. Thus, the thickness of the bottom plate is added to the thickness of the finished semiconductor device. In other words, it is difficult to make the semiconductor device thin.

### SUMMARY OF THE INVENTION

One object of the present invention is to reduce a thickness of a semiconductor device even if the semiconductor device has a package to hermetically seal a semiconductor chip.

According to a first aspect of the present invention, there is provided a semiconductor device that includes a bottomless package, and a semiconductor chip disposed in a chip installation-side opening (lower opening) of the package such that a lower surface of the semiconductor chip is coplanar to a lower surface of the package. The semiconductor device also includes a sealing lid. The sealing lid lies opposite the upper face of the semiconductor chip and closes the lid-side opening (upper opening) of the package. The semiconductor device also includes a binding layer. The binding layer seals the gap between the side face of the semiconductor chip and the inside face of the package and secures the semiconductor chip. Therefore, the lower opening of the bottomless package is closed by the binding layer and the semiconductor chip.

The lower face of the semiconductor chip is used as a bottom plate of the semiconductor device. Thus, the bottomless package together with the lower face of the semiconductor chip, bonding layer and lid is able to hermetically seal the semiconductor chip in the chip storage space. Because a separate lower plate is not provided (i.e., the lower plate is omitted), it is possible to reduce the thickness of the semiconductor device that has a package containing the semiconductor chip.

According to a second aspect of the present invention, there is provided a method of fabricating a semiconductor device. The method includes placing a bottomless package having a lower opening and an upper opening, on an adhesive layer of a carrier tape. The method also includes placing a semiconductor chip in the bottomless package such that a lower face of the semiconductor chip is put on the adhesive layer of the carrier tape. The method also includes feeding a binding agent into a gap between a side face of the semiconductor chip and an inside face of the package and curing the binding agent to form a binding layer that seals the gap between the side face of the semiconductor chip and the inside face of the package. The method also includes placing a lid on the package to close the upper opening of the package to seal an interior of the package. The method also includes removing the package from the carrier tape.

These and other objects, aspects and advantages of the present invention will become apparent to those skilled in the art when the following detailed description and appended claims are read and understood in conjunction with the accompanying drawings.

### BRIEF DESCRIPTION OF THE DRAWINGS

FIG. 1 is a cross-sectional view of a semiconductor device of a first embodiment of the present invention, taken along the line I-I in FIG. 2;

FIG. 2 is a top view of the semiconductor device of the first embodiment without a lid;

FIG. 3 is a cross-sectional view of the package of the semiconductor device shown in FIG. 1;

FIG. 4 is a top view of a carrier tape of the first embodiment;

FIG. 5A to FIG. 5E is a series of diagrams to show the fabrication process of the semiconductor device of the first embodiment; and

FIG. 6A to FIG. 6F is a series of diagrams of the fabrication process of the semiconductor device according to the second embodiment of the present invention.

### DETAILED DESCRIPTION OF THE INVENTION

Embodiments of the semiconductor device of the present invention and a method of fabricating same will be described hereinbelow with reference to the accompanying drawings.

### FIRST EMBODIMENT

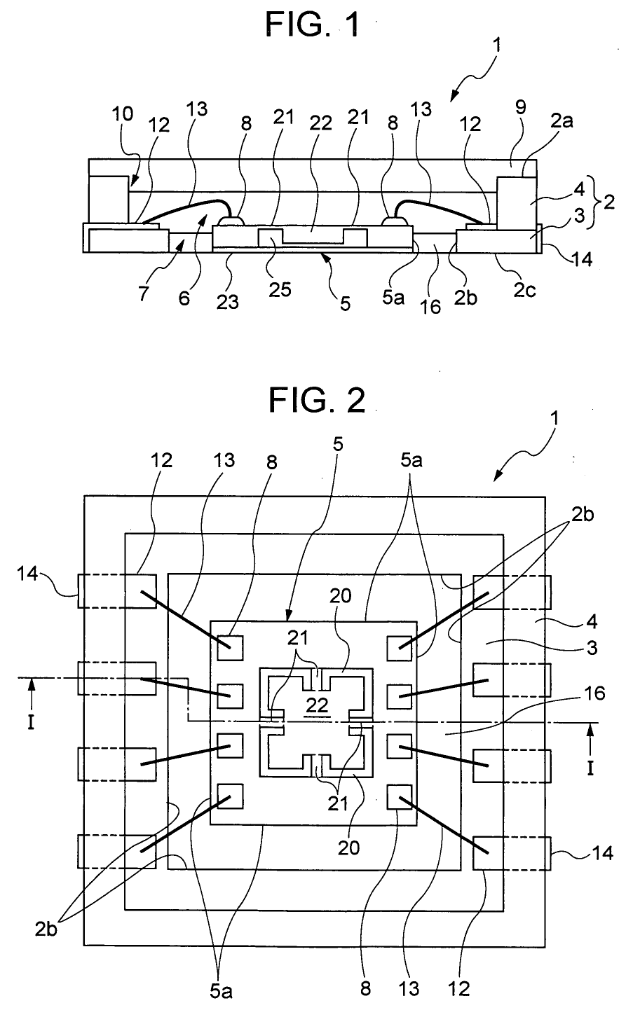

Referring to FIGS. 1 to 5E, a semiconductor device 1 of the first embodiment of the present invention will be described.

FIG. 2 is a plan view of the semiconductor device 1 without a sealing lid 9. The sealing lid 9 is shown in FIG. 1.

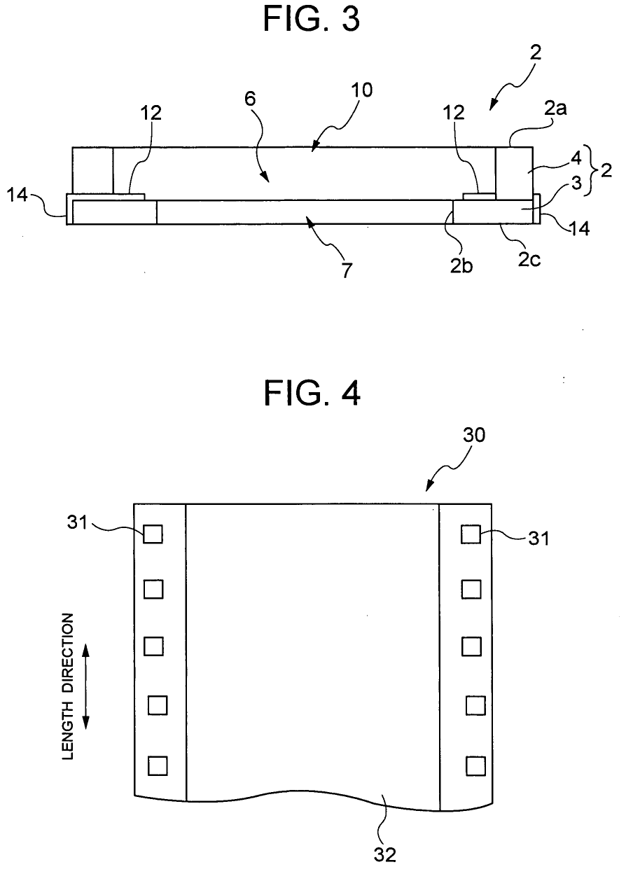

The semiconductor device 1 has a package 2. The package 2 is a bottomless frame with a substantially U-shaped cross-section as shown in FIG. 3. The package 2 is made from a ceramic material. The package 2 has a terminal formation plate (bottom plate) 3 and a side wall 4. The plate 3 has a large square hole 7 at the center thereof. The side wall 4 has a square frame shape to follow the outer edge of the terminal formation plate 3. The space inside the package 2, defined by the terminal formation plate 3 and side wall 4, functions as a chip storage space 6 to store hermetically seal a semiconductor chip 5 (FIG. 1).

As shown in FIG. 1, the semiconductor chip 5 is disposed in the opening 7 (referred to as the “chip installation-side opening 7”) of the terminal formation plate 3 of the chip storage space 6. An internal circuit of the semiconductor chip 5 is formed on one face of the semiconductor chip 5 (the upper face of the semiconductor chip 5 in FIG. 1). A plurality of pads 8, which are electrically connected to a predetermined part of the internal circuit, is formed on the upper face of the semiconductor chip 5. The terms “upper” and “lower” are used as observed in FIG. 1.

A sealing lid 9 is made from a ceramic material. The sealing lid 9 is bonded to a lid-side end face 2a of the package 2 to cover (close) the upper opening 10 (referred to as the “lid-side opening 10”) of the chip storage space 6. The opening 10 can be called “upper opening of the package 2.” The opening 7 of the terminal formation plate 3 can be said a lower opening of the chip storage space 6 or a lower opening of the package 2.

In order to fix the sealing lid 9 to the lid-side end face 2a, an adhesive or a paste such as silver paste or insulating paste is applied to the lid-side end face 2a, and cured after the lid 9 is put in position. Alternatively, the sealing lid 9 and lid-side end face 2a may be joined to each other by alloy brazing. The brazing involves placing a brazing alloy such as a metal foil made from silver or gold and tin between the lid-side end face 2a and the sealing lid 9 and causing the brazing alloy to melt by means of a heat treatment.

Internal terminals 12 are connection terminals formed on the upper face of the terminal formation plate 3 in the chip storage space 6. The internal terminals 12 are electrically connected to the pads 8 of the semiconductor chip 5 by means of wires 13. The wires 13 are narrow conductive wires made from a metal such as gold or aluminum.

External terminals 14 are connection terminals that relay signals between the semiconductor device 1 and external circuits (not shown). The external terminals 14 are formed on the outer side of the terminal formation plate 3 of the package 2. The external terminals 14 are electrically connected, directly or via a lead wire, to wiring terminals of a wiring substrate (not shown). The external circuits are provided on the wiring substrate. As a result, the external circuits and the internal circuit(s) of the semiconductor chip 5 are electrically connected via the external terminals 14, internal terminals 12, wires 13, and pads 8. The internal terminals 12 are associated with the external terminals 14, respectively.

Each internal terminal 12 and the corresponding external terminal 14 of this embodiment are made in a one-piece L-shaped element as shown in the left of FIG. 1, and provided on the terminal formation plate 3. More specifically, the L-shaped elements (combinations of the terminals 12 and 14) are placed and fixed between the terminal formation plate 3 and side wall 4 when the terminal formation plate 3 and side wall 4 are fixed to each other.

A binding layer 16 is provided in the chip-installation-side opening 7. In order to provide the binding layer 16, a liquid binding agent 17, which is a resin-based or epoxy-based heat-curable adhesive, fills the gap between a lateral wall 2b of the chip installation-side opening 7 of the package 2 and a lateral wall 5a of the semiconductor chip 5 and then is cured. The binding layer 16 binds and fixes the semiconductor chip 5 in the chip installation-side opening 7 of the chip storage space 6 of the package 2 and seals the gap between the package inside face 2b and chip outside face 5a.

The upper face of the semiconductor chip 5 where the internal circuit is provided is hermetically sealed in the chip storage space 6 by closing the chip installation-side opening 7 of the chip storage space 6 with the bonding layer 16 and semiconductor chip 5 and closing the lid-side opening 10 of the chip storage space 6 with the sealing lid 9.

The lower face of the semiconductor chip 5, lower face of the binding layer 16 and lower face 2c of the package 2 are substantially coplanar to each other.

The semiconductor chip 5 of this embodiment is a semiconductor acceleration sensor. As shown in FIGS. 1 and 2, this acceleration sensor includes a square main body 29, four short arms 21 and a weight (plumb) portion 22. The four short arms 21 are defined by four C-shaped slits 20. The arms 21 have a reduced thickness, if compared to other portions of the semiconductor chip, so that the arms 21 are bendable. As best seen in FIG. 1, the lower face of the arms 21 are ground to reduce the thickness. The weight portion 22 is a center piece and supported by the arms 21 such that it can move. The slits 20 penetrate the semiconductor chip 5 in the thickness direction of the semiconductor chip 5. Piezoresistive elements are provided in the arms 21 to establish a bridge circuit as the inner circuit, and this bridge circuit is electrically connected to the pads 8 provided on the upper face of the semiconductor chip 5. The semiconductor chip 5 has a glass plate 23 attached to the lower face thereof. The semiconductor chip 5 has, therefore, a hollow portion 25 inside itself.

In FIG. 4, a carrier tape 30 is a photographic film-like tape made of resin material (e.g., a polyimide-based or polyester-based resin material). Sprocket holes 31 are provided along longitudinal edges of the carrier tape 30.

The carrier tape 30 has an adhesive layer 32 on an upper face thereof. The adhesive layer 32 is provided to secure the package 2 and semiconductor chip 5 and so forth on the carrier tape 30 as a result of its adhesive (sticking) quality. The adhesive layer 32 is prepared by a suitable adhesive.

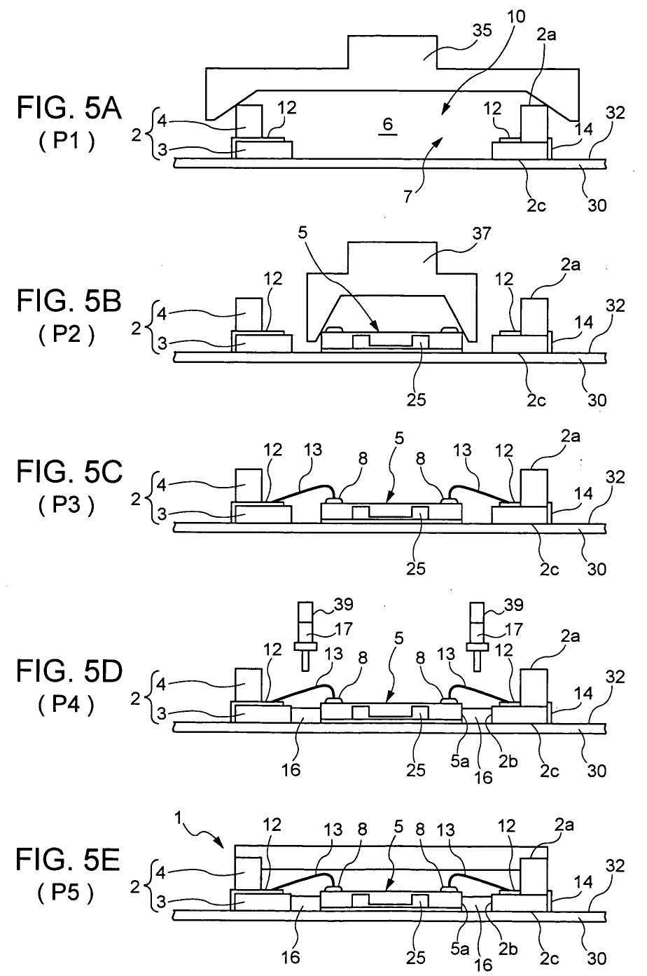

In FIG. 5A, a package collet 35 is made from a metal material, resin material or rubber material. The package collet 35 has slits or holes arranged to face the upper end face 2a of the package 2 to hold the package 2 through attraction by means of a negative pressure. The package collet 35 conveys the package 2 to the carrier tape 30 for installation thereon.

In FIG. 5B, a chip collet 37 is made from a metal material, resin material or rubber material. The chip collet 37 has slits or holes arranged to face the edge of the upper face of the semiconductor chip 5 to hold the semiconductor chip 5 through attraction by means of a negative pressure, and convey the semiconductor chip 5 to the carrier tape 30 for installation thereon.

In FIG. 5D, a binding agent nozzle 39 supplies the liquid binding agent 17 from its discharge opening to fill the gap between the lateral wall 2b of the chip installation-side opening 7 and the lateral wall 5a of the semiconductor chip 5.

A fabrication process for the semiconductor device of this embodiment will be described hereinbelow in accordance with FIG. 5A (step P1) to FIG. 5E (step P5).

In the fabrication process of this embodiment, the sealing lid 9 and package 2 shown in FIG. 3 are prepared in advance. The package 2 is for example put in a tray, and the sealing lid 9 is for example put in another tray.

Also, the semiconductor chip 5 (semiconductor acceleration sensor in this embodiment) having the hollow portion 25 is fabricated in advance by using a semiconductor wafer. The semiconductor wafer is divided into individual pieces, and one of the pieces is the semiconductor chip 5. The semiconductor chip 5 is for example put in a container.

P1 (FIG. 5A): The carrier tape 30 is placed on a conveying device (not shown) such that the adhesive layer 32 of the carrier tape 30 is directed upward. The conveying device has a pair of rails with sprockets (not shown) that engage with the sprocket holes 31 of the carrier tape 30. The carrier tape 30 is conveyed by the rotating sprockets of the conveying device, and stopped in the position where the package collet 35 is installed.

In the meantime, the package 2 is lifted from the tray and conveyed to the carrier tape 30 by the package collet 35 such that the chip-side end face 2c of the package 2 is stuck to the adhesive face 32 of the carrier tape 30. Thus, the package 2 is installed on the carrier tape 30 (package bonding step).

P2 (FIG. 5B): Then, the conveying device is actuated to move the carrier tape 30 to the position where the chip collet 37 is installed. The semiconductor chip 5 is lifted from the container and conveyed to the carrier tape 30 by the chip collet 37. The semiconductor chip 5 is placed, from its lower face, in the chip storage space 6 of the package 2. The lower face of the semiconductor chip 5 is stuck to the adhesive face 32 of the carrier tape 30. Thus, the semiconductor chip 5 is installed on the carrier tape 30 in the center area of the chip installation-side opening 7 (die bonding step).

P3 (FIG. 5C): After that, the carrier tape 30 is conveyed to the position where a wire bonder (not shown) is installed. Wires 13 are then connected between the pads 8 of the semiconductor chip 5 and the internal terminals 12 (wire bonding step).

P4 (FIG. 5D): Subsequently, the carrier tape 30 is conveyed to the position where the binding agent nozzles 39 are installed. The binding agent nozzles 39 supply the liquid binding agent 17 to fill the gap between the lateral face 2b of the chip installation-side opening 7 of the package 2 and the lateral face 5a of the semiconductor chip 5. Then, the binding agent 17 is cured by means of heat treatment or the like to form the binding layer 16 that seals between the package inside face 2b and chip side face 5a. The semiconductor chip 5 is thus fixed to the chip installation-side opening 7 of the chip storage space 6 of the package 2 (binding layer formation step).

The filling of the binding agent 17 between the package inside face 2b and chip side face 5a is executed so that the height of the chip side face 5a is not exceeded by the binding agent 17. As a result, the binding agent 17 is prevented from flowing into the hollow portion 25 of the semiconductor chip 5.

P5 (FIG. 5E): Then, the carrier tape 30 is conveyed to the position where a sealing lid collet (not shown) is installed and nozzles (not shown) are installed. The sealing lid collect holds the upper face of the sealing lid 9 by means of a negative pressure. The nozzles like the binding agent nozzles 39 apply adhesive to the lid-side end face 2a of the package 2. The sealing lid 9 is conveyed over the package 2 by the sealing lid collet such that the edge of the lower face of the sealing lid 9 is in contact with the lid-side end face 2a. Then, the adhesive is cured by means of a heat treatment or the like to bond the sealing lid 9 to the lid-side end face 2a. Accordingly, the lid-side opening 10 of the chip storage space 6 of the package 2 is sealed (package sealing step).

As a result, the upper face of the semiconductor chip 5 where the internal circuit of the semiconductor chip 5 is formed is sealed in the chip storage space 6.

Thereafter, the semiconductor device 1 is peeled from the carrier tape 30. Thus, the semiconductor device 1 of this embodiment, which is shown in FIGS. 1 and 2, is fabricated.

The lower face of the resulting semiconductor device 1 is constituted by the chip-side end face 2c of the package 2, the lower face of the binding layer 16 and the lower face 23 of the semiconductor chip 5. Because these lower faces are substantially coplanar to each other, the thickness of the semiconductor device 1 can be the sum of the minimum height required for the semiconductor chip 5 together with the wire loop and the thickness between the upper face of the sealing lid 9 and lid-side end face 2a of the package 2. Thus, a semiconductor device 1 with a thin thickness can be established.

Because the lower face of the semiconductor chip 5 is used as the bottom plate of the package 2, the upper face of the semiconductor chip 5 can be hermetically sealed in the chip storage space 6 even if the bottomless package 2 is employed.

The upper side of the semiconductor chip 5 is hermetically sealed in the chip storage space 6 by the sealing lid 9. Therefore, not only is it possible to maintain the functions of the semiconductor chip over long periods without foreign matter such as moisture and trash from the outside invading the hollow portion 25 of the semiconductor chip 5, it is also possible to protect the internal circuit and wires 13 on the upper face of the semiconductor chip 5 from shock and damage caused by collision with tools and other parts during the operation of mounting the semiconductor device 1 on the wiring substrate and attaching the semiconductor-device-mounted wiring substrate to a main apparatus.

Because the package 2 and semiconductor chip 5 are stuck to the carrier tape 30 having the adhesive layer 32 and conveyed between each of the processing steps (processing sites) by the carrier tape 30, the formation of a continuous fabrication line is straightforward and the production efficiency of the semiconductor device 1 can be improved.

It should be noted that a plurality of packages 2 arranged in the matrix form on a single plate member may be prepared and placed near the P1 processing site, and a cutting machine may also be provided. By cutting this plate member into individual packages 2, each package 2 can be quickly supplied on the carrier tape 30. The package installation by the package collet 35 becomes easier, and the tray or container for storing the package(s) 2 is not necessary. The lifting/carrying distance of the package by the package collet 35 is also reduced. Likewise, a plurality of sealing lids 9 arranged in the matrix from on a single plate member may be prepared and placed near the P5 processing site, and a cutting machine may also be provided. By cutting this plate member into individual sealing lids 9, each sealing lid 9 can be quickly supplied to the package 2. The sealing lid installation by the collect becomes easier, and the tray for storing the sealing lid(s) 9 is unnecessary. Thus, the production efficiency of the semiconductor device 1 can be improved, and expenses for the trays are dispensed with.

Also, if the cutting apparatus for cutting the semiconductor wafer on which a plurality of semiconductor chips 5 is formed is installed on the P2 processing site, effects similar to those above can be obtained.

It should be noted that the semiconductor chip 5 may have a solid structure, instead of the above described hollow structure.

When the semiconductor chip 5 is a solid semiconductor chip, the binding agent 16 supplied in the package storage space 6 may cover the upper face of the semiconductor chip 5.

Even when the semiconductor chip 5 is a solid semiconductor chip, it is possible to protect the internal circuit and wires 13 on the upper face of the semiconductor chip 5 from shock and damage caused by collision with tools and other parts during the operation of mounting the semiconductor device 1 on the wiring substrate and attaching the wiring substrate to the main apparatus.

As described above, because the semiconductor chip disposed in the chip installation-side opening of the chip storage space of the bottomless package is bonded to the package by the binding layer and sealed, and the lid-side opening of the package is sealed by the sealing lid in this embodiment, the lower face of the semiconductor chip can be used as a bottom plate of the package, and the upper face of the semiconductor chip can be hermetically sealed in the chip storage space by the bottomless package. Further, the thickness of the semiconductor device having a package that hermetically seals the semiconductor chip can be reduced by omitting the lower plate of the package.

Furthermore, because the semiconductor chip that has a hollow structure is sealed in the package storage space, foreign matter from the outside can be prevented from invading the hollow portion of the semiconductor chip and the functions of the semiconductor chip of the hollow structure can be maintained over long periods.

In addition, because the package and semiconductor chip are stuck to the carrier tape having an adhesive layer, and a binding layer is formed between the chip side face and the package inside face of the chip installation-side opening of the chip storage space of the bottomless package, the lower face of the semiconductor device can easily be made substantially flat by using the lower face of the semiconductor chip, a semiconductor device of small thickness can be fabricated easily, and the formation of a continuous fabrication line is straightforward. Consequently, the production efficiency of the semiconductor device can be increased.

### SECOND EMBODIMENT

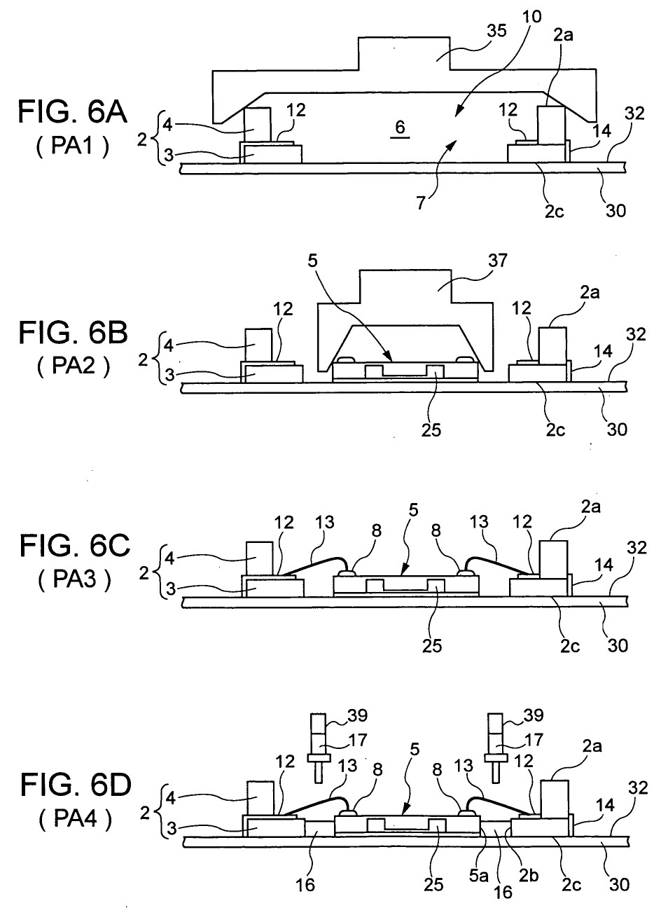

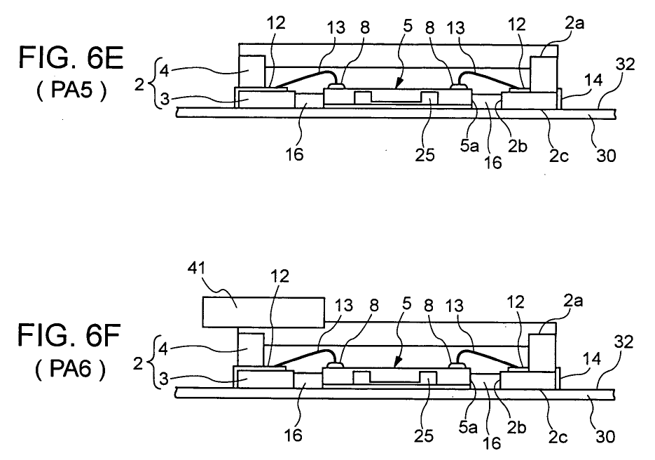

FIG. 6A to FIG. 6F are diagrams of the fabrication process of the semiconductor device according to the second embodiment of the present invention.

The same or similar symbols have been assigned to parts that are the same as those in the first embodiment in order to avoid repetition in the description.

In FIG. 6F, a disk-shaped whetstone 41 is used in a grinder. The whetstone 41 is made from abrasive grain using a binder. The whetstone 41 has sufficient hardness and grain diameter to grind the upper face of the sealing lid 9. In this embodiment, the sealing lid 9 is made from a ceramic material and, therefore, the whetstone 41 is made from abrasive grain of higher hardness such as a diamond.

The fabrication process of the semiconductor device 1′ of the second embodiment will be described hereinbelow with reference to FIG. 6A (step PA1) to FIG. 6F (step PA6).

The steps PA1 (FIG. 6A) to PA5 (FIG. 6E) of the second embodiment are not described here because these steps are the same as steps P1 to P5 in the first embodiment.

PA6 (FIG. 6F): After the step PA5, the carrier tape 30 is conveyed to the position where the grinder having the whetstone 41 is installed. Then, the thickness of the sealing lid 9 is reduced by grinding the upper face of the sealing lid 9 by means of the whetstone 41 (sealing lid grinding step).

The grinding is performed until the thickness between the upper face of the sealing lid 9 and the lid-side end face 2a of the package 2 becomes about 0.1 mm.

Thereafter, the semiconductor device 1′, which is stuck to the carrier tape 30, is peeled from the carrier tape 30. Thus, the semiconductor device 1′ of this embodiment is fabricated. The semiconductor device 1′ of this embodiment has a constitution similar to the semiconductor device 1 shown in FIG. 1 except for the fact that the thickness between the upper face of the sealing lid 9 of the semiconductor device 1′ and the lid-side end face 2a of the package 2 is smaller.

Like the first embodiment, the lower face of the semiconductor device 1′ is substantially coplanar to the lower face of the semiconductor chip 5. Further, the thickness between the upper face of the sealing lid 9 and the lid-side end face 2a of the package 2 is rendered the minimum thickness. Therefore, the thickness of the semiconductor device 1′ is the sum of the thickness of the semiconductor chip 5 together with the minimum space required for the wiring 13, and the reduced (minimum) thickness of the sealing lid 9. Thus, an even thinner semiconductor device 1′ (thickness of 1 mm or less, for example) can be fabricated.

It should be noted that the thickness of the sealing lid 9 is not reduced until the step PA6 in this embodiment. This is because the sealing lid 9 would be broken at the step PA5 if the thickness of the sealing lid 9 was too thin. In order to avoid such breakage, the thickness of the sealing lid 9 is first reduced at the step PA6.

As described above, the second embodiment has advantages similar to the first embodiment, and also has an additional advantage: the thickness between the upper face of the sealing lid and the lid-side end face of the package can be a minimum thickness. Thus, the thickness of the semiconductor device can be reduced still further.

Because the thickness of the sealing lid is reduced by grinding the upper face of the sealing lid in the step PA6 after the sealing lid has been bonded to the package, it is possible to prevent not only damage to the sealing lid during the bonding in the step PA5 but also prevent damage to the sealing lid during the grinding in the step PA6. Accordingly, the yield of the fabrication process can be improved and the semiconductor device can be made thin by means of a thin sealing lid.

In each of the above-described embodiments, the package 2 has a two-piece structure, which is created by bonding the terminal formation plate 3 and the side wall 4, but the terminal formation plate and side wall may be integrally formed and the package 2 may have a one-piece structure.

The material of the package 2 and sealing lid 9 is not limited to ceramic. For example, the material of the package and sealing lid may be resin. If the package 2 is made from the resin material, a plurality of L-shaped members, each made up by the internal terminal 12 and external terminal 14 in a one-piece structure, are resin-molded by means of insert molding, and the package 2 in which the terminal formation plate 3 and side wall 4 are integrated can be easily formed.

The location of the external terminals 14 is not limited to the outer periphery of the terminal formation plate 3. For instance, terminals 14 protrude from the lower face, there is the risk that the binding agent 16 will leak during filling.

Although the external terminals 14 (FIG. 1, FIG. 3, FIG. 5D, FIG. 6D) extend vertically downward to the chip-side end face 2c of the package 2 in the illustrated embodiments, the external terminals 14 may not extend to the chip-side end face 2c.

The carrier tape 30 may a photographic film-like thin metal plate having an adhesive layer on one face thereof.

This application is based on a Japanese Patent Application No. 2005-11995 filed on Jan. 19, 2005 and the entire disclosure thereof is incorporated herein by reference.

What is claimed is:

1. A semiconductor device comprising:
a bottomless package having a lower opening and an upper opening;
a semiconductor chip that is disposed in the package such that a lower surface of the semiconductor chip is substantially coplanar to the lower opening of the package;
a sealing lid that lies opposite an upper face of the semiconductor chip to close the upper opening of the package; and
a binding layer that seals a gap between a side face of the semiconductor chip and a side face of the package so as to close the lower opening of the package and secure the semiconductor chip.

2. The semiconductor device according to claim 1, wherein the semiconductor chip has a hollow structure.

3. The semiconductor device according to claim 1, wherein the semiconductor chip has a solid structure.

4. The semiconductor device according to claim 1, wherein the lower surface of the semiconductor chip defines a lower surface of the semiconductor device.

5. The semiconductor device according to claim 4, wherein the lower surface of the semiconductor chip includes a glass plate.

6. The semiconductor device according to claim 2, wherein the bonding layer does not extend over the semiconductor chip.

7. The semiconductor device according to claim 3, wherein the bonding layer extends over the semiconductor chip.

8. The semiconductor device according to claim 1, wherein a height of the semiconductor device is less than 1 mm.

9. A method of fabricating a semiconductor device comprising:
placing a bottomless package having a lower opening and an upper opening, on an adhesive layer of a carrier tape;
placing a semiconductor chip in the bottomless package such that a lower face of the semiconductor chip is put on the adhesive layer of the carrier tape;
feeding a binding agent into a gap between a side face of the semiconductor chip and an inside face of the package and curing the binding agent to form a binding layer that seals the gap between the side face of the semiconductor chip and the inside face of the package;
placing a lid on the package to close the upper opening of the package to seal an interior of the package; and
removing the package from the carrier tape.

10. The method of fabricating a semiconductor device according to claim 9 further comprising reducing a thickness of the sealing lid by grinding an upper face of the lid after the placing the lid on the package.

11. The method of fabricating a semiconductor device according to claim 9, wherein the feeding of the binding agent is performed such that an upper face of the semiconductor chip is not covered with the binding agent.

12. The method of fabricating a semiconductor device according to claim 9, wherein the feeding of the binding agent is performed such that an upper face of the semiconductor chip is covered with the binding agent.

13. The method of fabricating a semiconductor device according to claim 9, wherein the lower face of the semiconductor chip defines a lower face of the semiconductor device.

14. The method of fabricating a semiconductor device according to claim 13, wherein the lower surface of the semiconductor chip includes a glass plate.

15. The method of fabricating a semiconductor device according to claim 9 further comprising a wiring bonding step before the feeding of the binding agent.

16. The method of fabricating a semiconductor device according to claim 9, wherein a height of the semiconductor device is less than 1 mm.
